(19) United States
(12) Patent Application Publication
(10) Pub. No.: US 2026/0144091 A1
(43) Pub. Date: May 21, 2026

(54) CHIP PACKAGING UNIT WITH DUAL REDISTRIBUTION LAYER AND METHOD OF MANUFACTURING THE SAME

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/336,517

(22) Filed: Sep. 23, 2025

(30) Foreign Application Priority Data
Nov. 15, 2024 (TW) 113144067

(51) Int. Cl. H01L 23/00

(52) U.S. Cl. CPC H10W 70/60; H10W 70/09; H10W 72/0198

(57) ABSTRACT

A chip packaging unit with dual redistribution layers (RDL) and a method of manufacturing the same are provided. The chip packaging unit includes a chip, a first RDL disposed on a first surface of the chip, a second RDL arranged at a second surface of the chip, and at least one lateral surface connecting circuit. The chip is electrically connected to a plurality of external connection bodies on second conductive circuits through a plurality of die pads on the chip, a plurality of first conductive circuits of the first RDL, the lateral surface connecting circuits, and the second conductive circuits of the second RDL in turn. Then the chip is electrically connected to the outside through the external connection bodies. Thereby problems including complicated structure with larger thickness caused by arrangement of multiple layers of circuits or through silicon via can be solved and production cost is reduced.

### CROSS-REFERENCE TO RELATED APPLICATIONS

This non-provisional application claims priority under 35 U.S.C. §119(a) on Patent Application No(s). 113144067 filed in Taiwan, R.O.C. on Nov. 15, 2024, the entire contents of which are hereby incorporated by reference.

### BACKGROUND OF THE INVENTION

The present invention relates to a chip packaging unit and a method of manufacturing the same, especially to a chip packaging unit with dual redistribution layers (RDL) and a method of manufacturing the same.

In the field of chip packaging technology, a chip packaging unit available now is formed by a plurality of layers of circuits stacked over one another. Then a plurality of TSV holes is formed on the chip packaging unit by a through silicon via (TSV) process. Thereby chips inside can be electrically connected not only from one side/surface to another side/surface of the chip packaging unit but also the outside. However, the design of both multiple layers of circuits or the TSV holes is quite complicated so that the chip packaging unit produced is quite thick, unable to meet requirements for more compact design of the chip packaging now. The cost reduction is difficult. Besides the problems of thickness and cost, the TSV process might damage the chip.

### SUMMARY OF THE INVENTION

Therefore, it is a primary object of the present invention to provide a chip packaging unit with dual redistribution layers (RDL) and a method of manufacturing the same. The chip packaging unit includes a chip, a first RDL disposed on a first surface of the chip, a second RDL disposed on a second surface of the chip, and at least one lateral surface connecting circuit. The chip is electrically connected to the external connection bodies through a plurality of die pads on the chip, a plurality of first conductive circuits of the first RDL, the lateral surface connecting circuit, and a plurality of second conductive circuits of the second RDL in turn. Then the chip is further electrically connected to the outside through the external connection bodies. Thereby the problems of the chip packaging unit available now including complicated structure caused by arrangement of multiple layers of circuits or TSVs and a larger total thickness can be solved and this is beneficial to reduction of production cost.

In order to achieve the above objects, a chip packaging unit with dual redistribution layers (RDL) according to the present invention is provided. The chip packaging unit is a rectangular cuboid with four side surfaces. The chip packaging unit includes a chip, a first RDL, a second RDL, and at least one lateral surface connecting circuit. The chip is a rectangular cuboid having a first surface, and a second surface opposite to the first surface, and four lateral surfaces. A plurality of die pads is disposed on the first surface of the chip. The first RDL is formed on the first surface of the chip by a RDL process and provided with a plurality of first conductive circuits. The respective first conductive circuits are made of metals and electrically connected to the respective die pads correspondingly. The second RDL is formed on the second surface of the chip by the RDL process and provided with a plurality of second conductive circuits and a plurality of external connection bodies. The respective second conductive circuits are formed by metals and the external connection bodies are formed by metals and disposed over the second conductive circuits. The lateral surface connecting circuits are made of metals, located at the side surfaces of the chip packaging unit correspondingly, and arranged at the lateral surfaces of the chip. The lateral surface connecting circuits are located between the first RDL and the second RDL and electrically connected to both the first conductive circuits and the second conductive circuits. The chip is electrically connected to the external connection bodies through the die pads, the first conductive circuits, the lateral surface connecting circuits, and the second conductive circuits in turn. Then the chip is further electrically connected to the outside through the external connection bodies. The chip packaging unit is formed by performing a cutting process of a wafer. The wafer includes a first surface and a second surface opposite to the first surface. The wafer is provided with a plurality of the chip packaging units arranged in an array and adjacent to each other. A cutting area is formed between the two adjacent chip packaging units and a plurality of conductive through holes is mounted to each of the cutting areas and axially penetrating from the first surface to the second surface. Each of the conductive through holes is located at an outer edge of the lateral surface of the chip of the chip packaging unit. Each of the conductive through holes is provided with an axial connecting circuit made of metals. The axial connecting circuit is located between the first RDL and the second RDL of the chip packaging unit and electrically connected to the first conductive circuits and the second conductive circuits. The cutting process is performed by using a cutting tool to cut the wafer along the respective cutting areas of the wafer. After the cutting areas being cut, a cutting street with a width smaller than a width of the cutting area is formed on the cutting area. During formation of the respective cutting street, a part of the conductive through hole and a part of the axial connecting circuit are also cut and removed at the same time. The rest part of the axial connecting circuit and the rest part of the conductive through hole are left on the outer edge of the lateral surface of the chip to form the lateral surface connecting circuit of the chip packaging unit.

Preferably, a diameter of the conductive through hole of the wafer is larger than the width of the cutting street.

Preferably, the first RDL further includes a first dielectric layer provided with a plurality of first grooves each of which is used for allowing the corresponding die pad of the chip to be exposed. The first conductive circuits are formed by a metal paste filled into the first grooves. The second RDL further includes a second dielectric layer provided with a plurality of second grooves. The second conductive circuits are formed by a metal paste filled into the second grooves.

Preferably, the metal pastes of the first conductive circuits and the second conductive circuits include silver paste, nano-scale silver paste, copper paste, and nano-scale copper paste.

Preferably, the external connection bodies are solder balls.

A method of manufacturing the chip packaging unit includes the following steps. Step S1: providing a wafer having a first surface, a second surface opposite to the first surface, a plurality of chips arranged in an array and located adjacent to each other. Each of the chips is having four lateral surfaces. Each of the chips has a first surface, a second surface, and a plurality of die pads disposed on the first surface of the chip. A cutting area is formed between the two adjacent chips and provided with a plurality of conductive through holes axially penetrating from the first surface to the second surface of the wafer. Each of the conductive through holes is located at an outer edge of at least one the lateral surfaces of the chip ad provided with an axial connecting circuit therein. The respective axial connecting circuits are made of metals. Step S2: paving a first RDL over the first surface of each of the chips, the first surface of the wafer, and one end of the axial connecting circuits by a RDL process. The first RDL includes a plurality of first conductive circuits each of which is made of metals and electrically connected to the axial connecting circuit. Step S3: paving a second RDL over the second surface of each of the chips, the second surface of the wafer, and one end of the axial connecting circuits by the RDL process. The second RDL includes a plurality of second conductive circuits each of which is electrically connected to the axial connecting circuit correspondingly. Each of the second conductive circuits is made of metals and provided with a plurality of the external connection bodies which are made of metals. Step S4: using a cutting tool to cut the wafer along the cutting areas of the wafer to form a cutting street on each of the cutting areas and a width of the cutting street is smaller than a width of the corresponding cutting area. During formation of the cutting street, a part of the conductive through hole and a part of the axial connecting circuit are also cut and removed at the same time. The rest part of the axial connecting circuit and the rest part of the conductive through hole are left on the outer edge of the lateral surface of the chip to form at least one lateral surface connecting circuit. The lateral surface connecting circuit is located between the first RDL and the second RDL and electrically connected to the first conductive circuits and the second conductive circuits. Step S5: forming a plurality of the chip packaging units after completing cutting of the wafer. The chip of the chip packaging unit is electrically connected to the external connection bodies through the die pads, the first conductive circuits, the lateral surface connecting circuits, and the second conductive circuits in turn. Then the chip is further electrically connected to the outside through the external connection bodies.

Preferably, in the step S2, a metal paste is filled into grooves and then the metal paste is ground to form a plurality of the first conductive circuits on the first RDL over the chip. First paving a first dielectric layer over the first surface of each of the chips, the first surface of the wafer, and one end of the axial connecting circuits. Then forming a plurality of first grooves horizontally on the first dielectric layer and each of the first grooves is for allowing the one end of the axial connecting circuit to be exposed. Next filling a metal paste into the first grooves and a level of the metal paste is higher than a surface of the first dielectric layer. Later grinding the metal paste with the level higher than the surface of the first dielectric layer to make a surface of the metal paste flush with the surface of the first dielectric layer and form the first conductive circuit.

Preferably, in the step S3, a metal paste is filled into grooves and then the metal paste is ground to form a plurality of the second conductive circuits on the second RDL over the chip. First paving a second dielectric layer over the second surface of each of the chips, the second surface of the wafer, and one end of the axial connecting circuits. Then forming a plurality of second grooves horizontally on the second dielectric layer and each of the second grooves is for allowing the one end of the axial connecting circuit to be exposed. Next filling a metal paste into the second grooves and a level of the metal paste is higher than a surface of the second dielectric layer. Later grinding the metal paste with the level higher than the surface of the second dielectric layer to make a surface of the metal paste flush with the surface of the second dielectric layer and form the second conductive circuits.

### BRIEF DESCRIPTION OF THE DRAWINGS

FIG. 1 is a side sectional view of an embodiment of a chip packaging unit according to the present invention;

FIG. 2 is a top view of an embodiment of a wafer according to the present invention;

FIG. 3 is a side sectional view of an embodiment of a wafer according to the present invention;

FIG. 4 is a partial enlarged view of the embodiment in FIG. 3 according to the present invention;

FIG. 5 is a side sectional view of an embodiment of a chip according to the present invention;

FIG. 6 is a schematic drawing showing an axial connecting circuit located at an outer edge of a lateral surface of the chip of the embodiment in FIG. 5 according to the present invention;

FIG. 7 is a schematic drawing showing a first dielectric layer arranged over the chip of the embodiment in FIG. 6 according to the present invention;

FIG. 8 is a schematic drawing showing a metal paste filled into first grooves of the embodiment in FIG. 7 according to the present invention;

FIG. 9 is a schematic drawing showing grinding of the metal paste to form first conductive circuits of the embodiment in FIG. 8 according to the present invention;

FIG. 10 is a schematic drawing showing a second dielectric layer arranged over the chip of the embodiment in FIG. 9 according to the present invention;

FIG. 11 is a schematic drawing showing a metal paste filled into second grooves of the embodiment in FIG. 10 according to the present invention;

FIG. 12 is a schematic drawing showing grinding of the metal paste to form second conductive circuits of the embodiment in FIG. 11 according to the present invention;

FIG. 13 is a schematic drawing showing the second conductive circuits provided with external connection bodies of the embodiment in FIG. 12 according to the present invention;

FIG. 14 is a top view of an embodiment of another wafer according to the present invention;

FIG. 15 is a side sectional view of another embodiment of a chip packaging unit according to the present invention.

### DETAILED DESCRIPTION OF THE PREFERRED EMBODIMENT

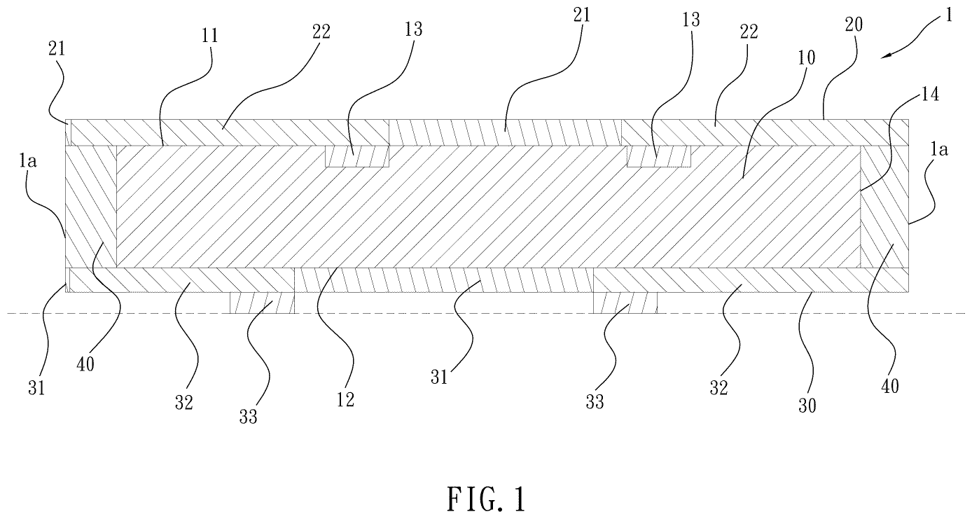

Refer to FIG. 1, a chip packaging unit 1 with dual redistribution layers (RDL) according to the present invention is a rectangular cuboid with four side surfaces 1a. The chip packaging unit 1 includes a chip 10, a first RDL 20, a second RDL 30, and at least one lateral surface connecting circuit 40.

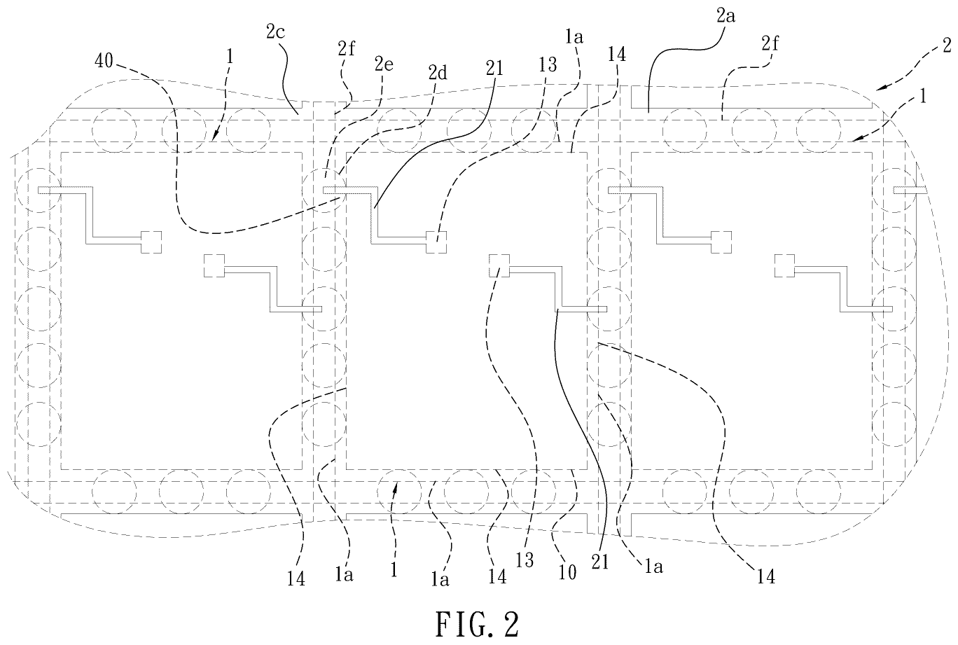

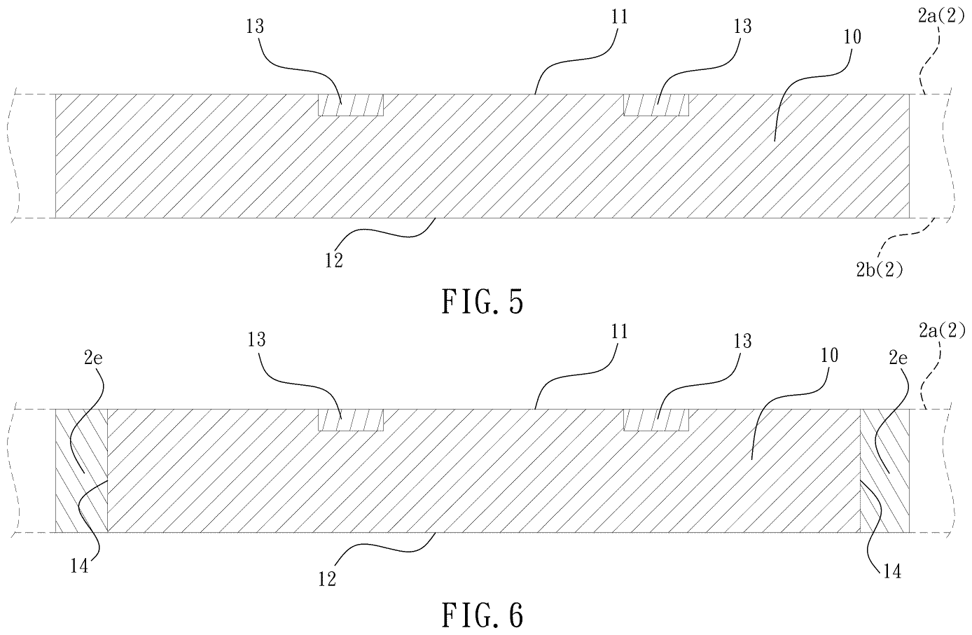

The chip 10 has a first surface 11 and a second surface 12 opposite to the first surface 11. A plurality of die pads 13 is disposed on the first surface 11 of the chip 10, as shown in FIG. 5. The chip 10 is a rectangular cuboid having four lateral surfaces 14, as shown in FIG. 2. In FIG. 1, there are two die pads 13 but the number of the die pads 13 is not limited.

The first RDL 20 is formed on the first surface 11 of the chip 10 by a redistribution layer (RDL) process and provided with a plurality of first conductive circuits 22, as shown in FIG. 1. The respective first conductive circuits 22 are formed by metals and electrically connected to the respective die pads 13 correspondingly.

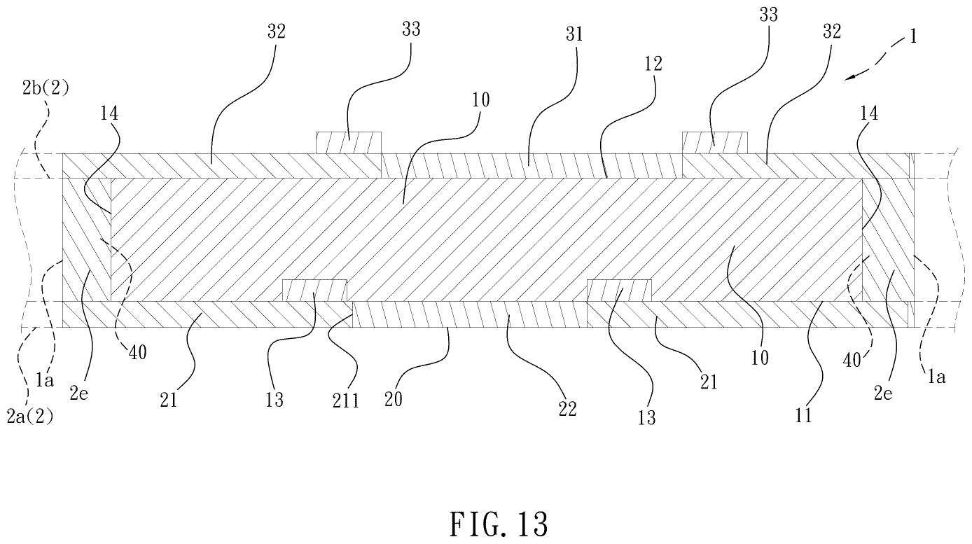

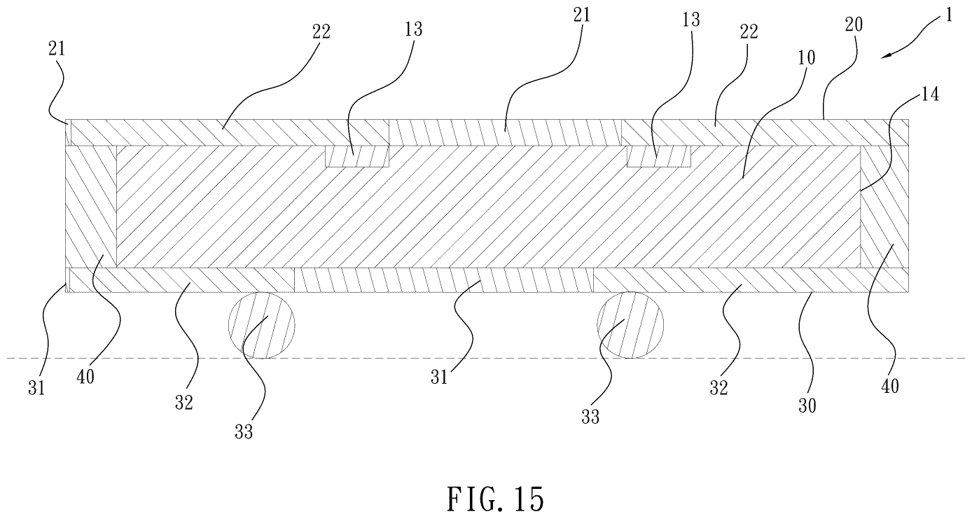

Refer to FIG. 1, the second RDL 30 is formed on the second surface 12 of the chip 10 by the RDL process and provided with a plurality of second conductive circuits 32 and a plurality of external connection bodies 33. The respective second conductive circuits 32 are formed by metals and the external connection bodies 33 are formed by metals and disposed over the second conductive circuits 32, as shown in FIG. 1, FIG. 13, and FIG. 15.

Refer to FIG. 1, the lateral surface connecting circuits 40 are made of metals, located at the side surfaces 1a correspondingly, and arranged at the lateral surfaces 14 of the chip 10 correspondingly. The lateral surface connecting circuits 40 are located between the first RDL 20 and the second RDL 30 and electrically connected to both the first conductive circuits 22 and the second conductive circuits 32 correspondingly.

FIG. 1 and FIG. 15, the chip 10 is electrically connected to the external connection bodies 33 through the die pads 13, the first conductive circuits 22, the lateral surface connecting circuits 40, and the second conductive circuits 32 in turn. Then the chip 10 is further electrically connected to the outside through the external connection bodies 33.

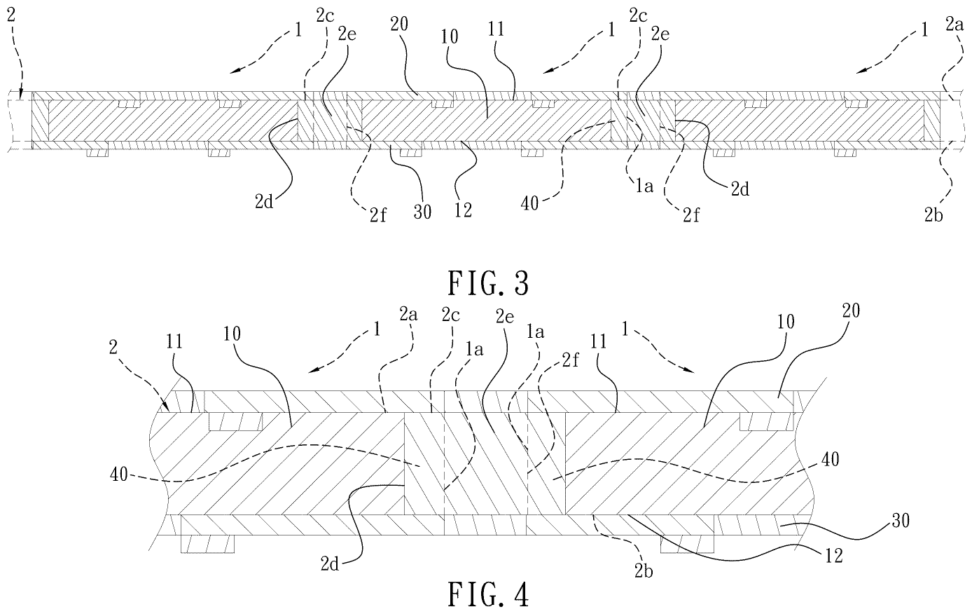

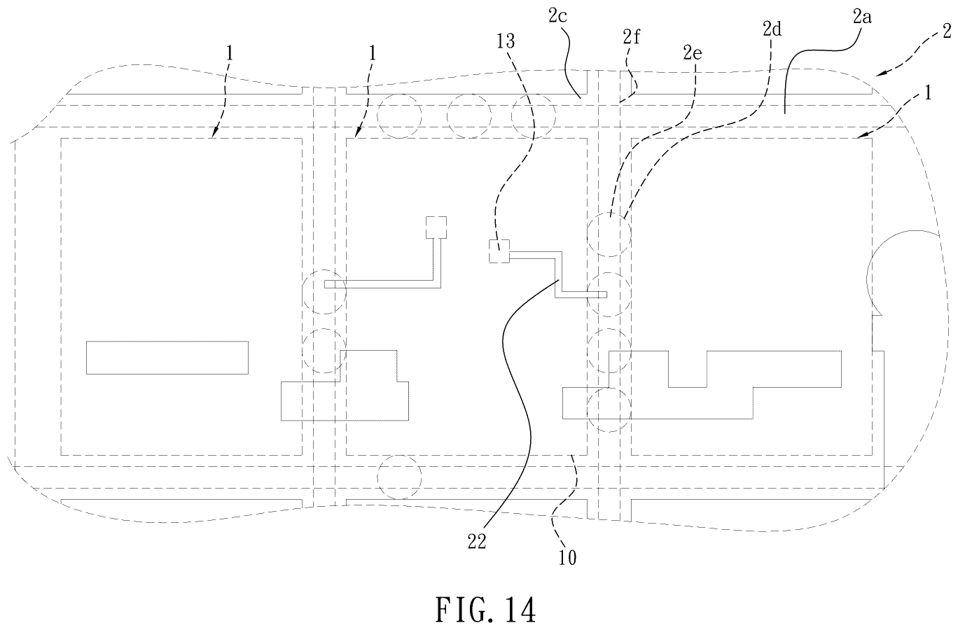

The chip packaging unit 1 is formed by performing a cutting process of a wafer 2. The wafer 2 includes a first surface 2a and a second surface 2b opposite to the first surface 2a, as shown in FIG. 3. The wafer 2 is provided with a plurality of the chip packaging units 1 arranged in an array and adjacent to each other. As shown in FIG. 2, a cutting area 2c is formed between the two adjacent chip packaging units 1 and a plurality of conductive through holes 2d is mounted to each of the cutting areas 2c and axially penetrating from the first surface 2a to the second surface 2b, as shown in FIG. 3 and FIG. 4. Each of the conductive through holes 2d is located at an outer edge of the lateral surface 14 of the chip 10 of the chip packaging unit 1, as shown in FIG. 2. Each of the respective conductive through holes 2d includes an axial connecting circuit 2e made of metals, as shown in FIG. 2 and FIG. 14. As shown in FIG. 3 and FIG. 4, the axial connecting circuits 2e are located between the first RDL 20 and the second RDL 30 of the chip packaging unit 1 and electrically connected to the first conductive circuits 22 and the second conductive circuits 32, as shown in FIG. 13. The cutting process is performed by using a cutting tool to cut the wafer 2 along the respective cutting areas 2c of the wafer 2. After the cutting areas 2c being cut, a cutting street 2f with a width smaller than a width of the cutting area 2c is formed on the cutting area 2c, a shown in FIG. 2-4. During formation of the respective cutting streets 2f, a part of the conductive through hole 2d and a part of the axial connecting circuit 2e are also cut and removed at the same time, as shown in FIG. 2. The rest part of the axial connecting circuit 2e and the rest part of the conductive through hole 2d are left on the outer edge of the at least one lateral surface 14 of the chip 10 to form the lateral surface connecting circuit 40 of the chip packaging unit 1, as shown in FIG. 2.

Refer to FIG. 2, a diameter of the conductive through hole 2d of the wafer 2 is larger than the width of the cutting street 2f.

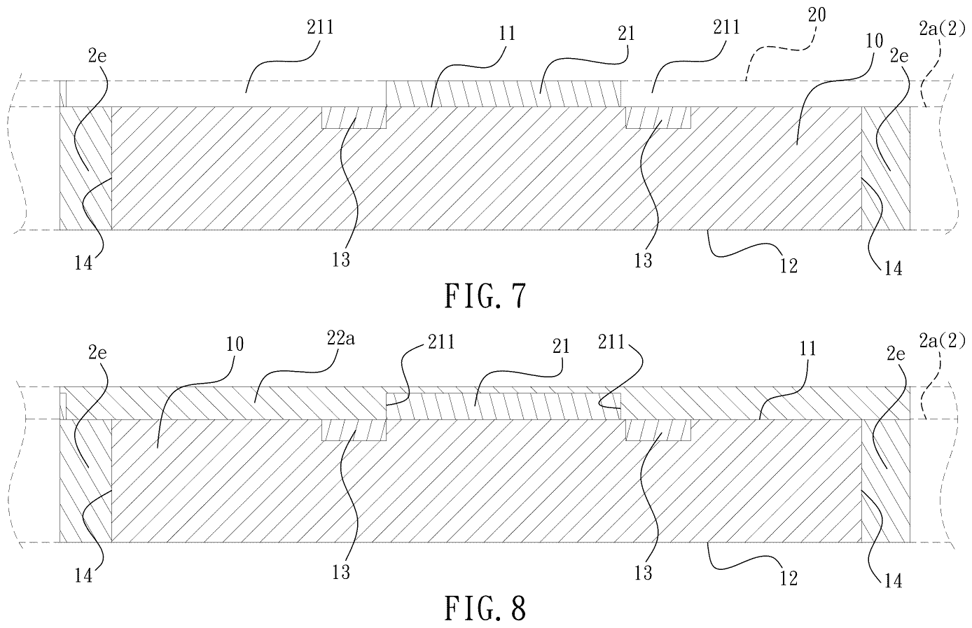

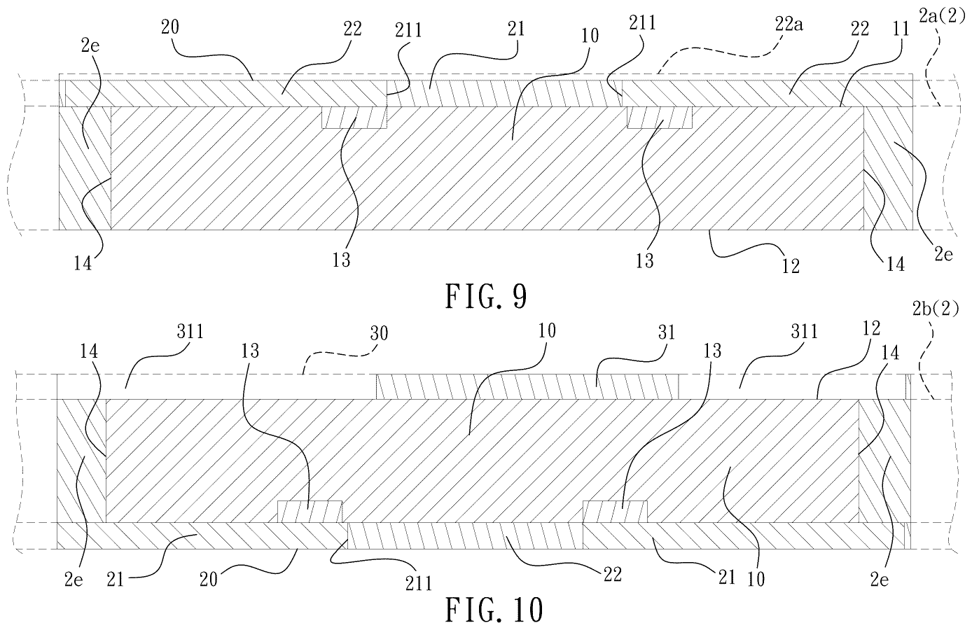

Refer to FIG. 7, the first RDL 20 further includes a first dielectric layer 21 provided with a plurality of first grooves 211 each of which is used for allowing the corresponding die pad 13 of the chip 10 to be exposed. The first conductive circuits 22 are formed by a metal paste 22a filled into the first grooves 211, as shown in FIG. 9. As shown in FIG. 10, the second RDL 30 further includes a second dielectric layer 31 provided with a plurality of second grooves 311. The second conductive circuits 32 are formed by a metal paste 32a filled into the second grooves 311, as shown in FIG. 12.

Refer to FIG. 9 and FIG. 12, The metal pastes 22a, 32a of the first conductive circuits 22 and the second conductive circuits 32 include silver paste, nano-scale silver paste, copper paste, and nano-scale copper paste.

Refer to FIG. 15, the external connection bodies 33 are solder balls which is beneficial to diverse applications of the products.

A method of manufacturing the chip packaging unit 1 includes the following steps.

Step S1: providing a wafer 2. The wafer 2 includes a first surface 2a and a second surface 2b opposite to the first surface 2a, as shown in FIG. 3. The wafer 2 is provided with a plurality of chips 10 each of which is arranged in an array, adjacent to each other, and having four lateral surfaces 14, as shown in FIG. 2. Each of the chips 10 has a first surface 11 and a second surface 12 and a plurality of die pads 13 is disposed on the first surface 11 of the chip 10, as shown in FIG. 5. As shown in Fig, 2, a cutting area 2c is formed between the two adjacent chips 10 and provided with a plurality of conductive through holes 2d axially penetrating from the first surface 2a to the second surface 2b of the wafer 2, as shown in FIG. 3 and FIG. 4. Each of the conductive through holes 2d is located at an outer edge of at least one of the lateral surfaces 14 of the chip 10 and having an axial connecting circuit 2e therein, as shown in FIG. 2. The respective axial connecting circuits 2e are made of metals.

Step S2: paving a first RDL 20 over the first surface 11 of each of the chips 10, the first surface 2a of the wafer 2, and one end of the axial connecting circuits 2e by a RDL process, as shown in FIG. 7. The first RDL 20 includes a plurality of first conductive circuits 22 each of which is electrically connected to the axial connecting circuit 2e correspondingly, as shown in FIG. 9. The first conductive circuits 22 are made of metals.

Step S3: paving a second RDL 30 over the second surface 12 of each of the chips 10, the second surface 2b of the wafer 2, and one end of the axial connecting circuits 2e by the RDL process, as shown in FIG. 10. The second RDL 30 includes a plurality of second conductive circuits 32 each of which is electrically connected to the axial connecting circuit 2e correspondingly, as shown in FIG. 12. Each of the second conductive circuits 32 is made of metals and provided with a plurality of the external connection bodies 33 made of metals, as shown in FIG. 13.

Step S4: using a cutting tool to cut the wafer 2 along the cutting areas 2c of the wafer 2 to form a cutting street 2f on each of the cutting areas 2c; a width of the cutting street 2f is smaller than a width of the corresponding cutting area 2c; during formation of the cutting street 2f, a part of the conductive through hole 2d and a part of the axial connecting circuit 2e are also cut and removed at the same time; the rest part of the axial connecting circuit 2e and the rest part of the conductive through hole 2d are left on the outer edge of at least one of the lateral surfaces 14 of the chip 10 to form at least one lateral surface connecting circuit 40 of the chip packaging unit 1. The lateral surface connecting circuit 40 is located between the first RDL 20 and the second RDL30 and electrically connected to the first conductive circuits 22 and the second conductive circuits 32, as shown in FIG. 1.

Step S5: forming a plurality of the chip packaging units 1 after completing cutting of the wafer 2, as shown in FIG. 3. As shown in FIG. 1, FIG. 13, and FIG. 15, the chip 10 of the chip packaging unit 1 is electrically connected to the external connection bodies 33 through the die pads 13, the first conductive circuits 22, the lateral surface connecting circuits 40, and the second conductive circuits 32 in turn. Then the chip 10 is further electrically connected to the outside through the external connection bodies 33.

In the step S2, a metal paste is filled into grooves and then the metal paste is ground to form a plurality of the first conductive circuits 22 on the first RDL 20 over the chip 10. First paving a first dielectric layer 21 over the first surface 11 of each of the chips 10, the first surface 2a of the wafer 2, and one end of the axial connecting circuits 2e. Then forming a plurality of first grooves 211 horizontally on the first dielectric layer 21 and each of the first grooves 211 is for allowing the one end of the axial connecting circuits 2e to be exposed, as shown in FIG. 7. Next filling a metal paste 22a into the first grooves 211 and a level of the metal paste 22a is higher than a surface of the first dielectric layer 21, as shown in FIG. 8. Later grinding the metal paste 22a with the level higher than the surface of the first dielectric layer 21 to make a surface of the metal paste 22a flush with the surface of the first dielectric layer 21 and form the first conductive circuits 22, as shown in FIG. 9.

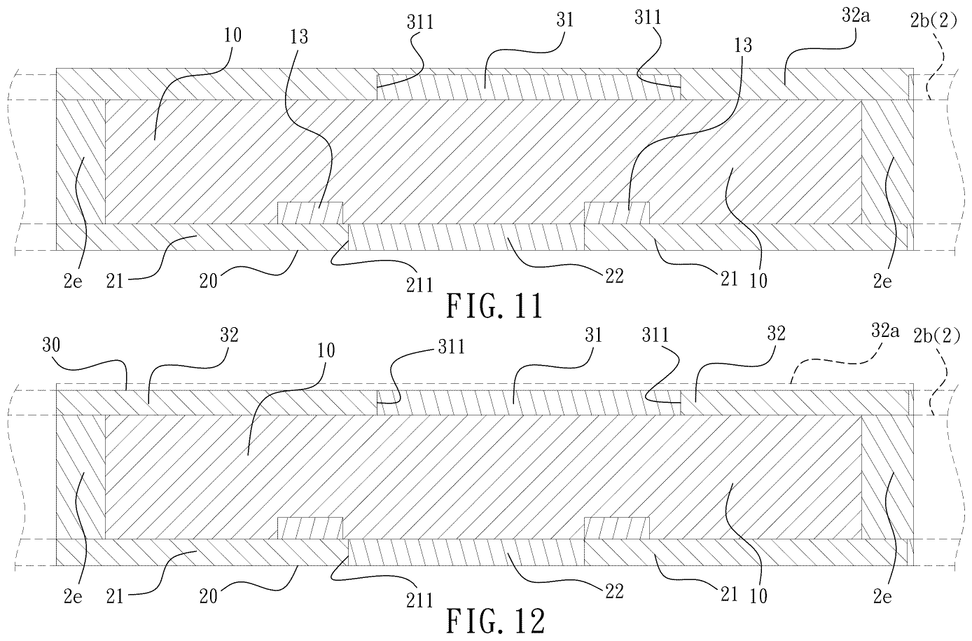

In the step S3, a metal paste is filled into grooves and then the metal paste is ground to form a plurality of the second conductive circuits 32 on the second RDL 30 over the chip 10. First paving a second dielectric layer 31 over the second surface 12 of each of the chips 10, the second surface 2b of the wafer 2, and one end of the axial connecting circuits 2e. Then forming a plurality of second grooves 311 horizontally on the second dielectric layer 31 and each of the second grooves 311 is for allowing the one end of the axial connecting circuit 2e to be exposed, as shown in FIG. 10. Next filling a metal paste 32a into the second grooves 311 and a level of the metal paste 32a is higher than a surface of the second dielectric layer 31, as shown in FIG. 11. Later grinding the metal paste 32a with the level higher than the surface of the second dielectric layer 31 to make a surface of the metal paste 32a flush with the surface of the second dielectric layer 31 and form the second conductive circuits 32, as shown in FIG. 12.

The formation processes of the first and the second conductive circuits 22, 32 can be considered as key steps of manufacturing the RDL of the chip packaging unit 1. Since these processes are precise and easily-implemented, the manufacturing process is simplified and the chip packaging unit 1 produced is still having a certain degree of light weight and compact volume under condition that the respective conductive circuits in the RDL have electrical extension in the XY plane and interconnections. The formation processes mentioned above in the preferred embodiments are not intended to limit the present invention.

Compared with the chip packaging technology available now, the present chip packaging units 1 has the following advantages.
(1) The first and second RDLs 20, 30 are formed over the first and the second surfaces 11, 12 of the chip 10 by the RDL process. The problem of the chip packaging unit available now with complicated design of multiple layers of circuits can be solved and this helps reduction of manufacturing cost.
(2) The first conductive circuits 22 and the second conductive circuits 32 on the two opposite surfaces 11, 12 of the chip 10 are electrically connected by the lateral surface connecting circuits 40 without using the Through Silicon Via (TSV) process. This helps in simplification of the manufacturing process and reduction of difficulty and cost of circuits design during manufacturing.
(3) In the step S4 of the manufacturing method of the chip packaging unit 1, it is provided that the lateral surface connecting circuits 40 are formed on the side surfaces 1a of the chip packaging unit 1 correspondingly after completing the cutting. Thus the formation process of the lateral surface connecting circuits 40 is simplified and this is beneficial to reduction of manufacturing cost.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A chip packaging unit with dual redistribution layers (RDL) being in a
rectangular shape and having four sides comprising:
a chip having a first surface, a second surface opposite to the first surface, and a plurality of die pads disposed on the first surface of the chip; the chip in a rectangular form and having four lateral surfaces;
a first RDL formed on the first surface of the chip by a RDL process and provided with a plurality of first conductive circuits made of metals and electrically connected to the die pads correspondingly;
a second RDL formed on the second surface of the chip by the RDL process and provided with a plurality of second conductive circuits and a plurality of external connection bodies; the respective second conductive circuits made of metals and the external connection bodies made of metals and disposed over the second conductive circuits; and
at least one lateral surface connecting circuit made of metals, located at the side surface of the chip packaging unit correspondingly, and arranged at the lateral surface of the chip; the lateral surface connecting circuit located between the first RDL and the second RDL and electrically connected to the first conductive circuits and the second conductive circuits;
wherein the chip is electrically connected to the external connection bodies through the die pads, the first conductive circuits, the lateral surface connecting circuit, and the second conductive circuits in turn; the chip is further electrically connected to the outside through the external connection bodies;
wherein the chip packaging unit is formed by performing a cutting process of a wafer; the wafer includes a first surface and a second surface opposite to the first surface; the wafer is provided with a plurality of the chip packaging units arranged in an array and adjacent to each other; a cutting area is formed between the two adjacent chip packaging units and a plurality of conductive through holes is mounted to each of the cutting areas and axially penetrating from the first surface to the second surface; each of the conductive through holes is located at an outer edge of the lateral surface of the chip of the chip packaging unit; each of the conductive through holes is provided with an axial connecting circuit made of metals; the axial connecting circuit is located between the first RDL and the second RDL of the chip packaging unit and electrically connected to the first conductive circuits and the second conductive circuits; wherein the cutting process is performed by using a cutting tool to cut the wafer along the respective cutting areas of the wafer; after the cutting areas being cut, a cutting street with a width smaller than a width of the cutting area is formed on the cutting area; during formation of the cutting street, a part of the conductive through hole and a part of the axial connecting circuit are cut and removed at the same time; the rest part of the axial connecting circuit and the rest part of the conductive through hole are left on the outer edge of the lateral surface of the chip to form the lateral surface connecting circuit of the chip packaging unit.

2. The chip packaging unit as claimed in claim 1, wherein a diameter of the conductive through hole of the wafer is larger than the width of the cutting street.

3. The chip packaging unit as claimed in claim 1, wherein the first RDL further includes a first dielectric layer provided with a plurality of first grooves each of which is used for allowing the corresponding die pad of the chip to be exposed; wherein the first conductive circuits are formed by a metal paste filled into the first grooves; wherein the second RDL further includes a second dielectric layer provided with a plurality of second grooves; wherein the second conductive circuits are formed by a metal paste filled into the second grooves.

4. The chip packaging unit as claimed in claim 1, wherein the external connection bodies are solder balls.

5. A method of manufacturing a chip packaging unit with dual redistribution layers (RDL) comprising the steps of:
Step S1: providing a wafer having a first surface, a second surface opposite to the first surface, a plurality of chips arranged in an array and located adjacent to each other; each of the chips having four lateral surfaces; wherein each of the chips has a first surface, a second surface, and a plurality of die pads disposed on the first surface of the chip; wherein a cutting area is formed between the two adjacent chips and provided with a plurality of conductive through holes axially penetrating from the first surface to the second surface of the wafer; each of the conductive through holes is located at an outer edge of at least one the lateral surfaces of the chip ad provided with an axial connecting circuit therein; the axial connecting circuits made of metals;
Step S2: paving a first RDL over the first surface of each of the chips, the first surface of the wafer, and one end of the axial connecting circuits by a RDL process; wherein the first RDL includes a plurality of first conductive circuits each of which is made of metals and electrically connected to the axial connecting circuit;
Step S3: paving a second RDL over the second surface of each of the chips, the second surface of the wafer, and one end of the axial connecting circuits by the RDL process; wherein the second RDL includes a plurality of second conductive circuits each of which is made of metals and electrically connected to the axial connecting circuit correspondingly; wherein each of the second conductive circuits is provided with a plurality of the external connection bodies which are made of metals;
Step S4: using a cutting tool to cut the wafer along the cutting areas of the wafer to form a cutting street on each of the cutting areas and a width of the cutting street is smaller than a width of the corresponding cutting area; during formation of the cutting street, a part of the conductive through hole and a part of the axial connecting circuit are cut and removed at the same time; the rest part of the axial connecting circuit and the rest part of the conductive through hole are left on the outer edge of the lateral surface of the chip to form at least one lateral surface connecting circuit; wherein the lateral surface connecting circuit is located between the first RDL and the second RDL and electrically connected to the first conductive circuits and the second conductive circuits; and
Step S5: forming a plurality of the chip packaging units after completing cutting of the wafer; wherein the chip of the chip packaging unit is electrically connected to the external connection bodies through the die pads, the first conductive circuits, the lateral surface connecting circuit, and the second conductive circuits in turn; the chip is further electrically connected to the outside through the external connection bodies.

6. The method of manufacturing a chip packaging unit with dual RDLs as claimed in claim 5, wherein the first RDL in the step S2 is produced by filling a metal paste into grooves and then grinding the metal paste to form a plurality of the first conductive circuits on over the chip; first paving a first dielectric layer over the first surface of each of the chips, the first surface of the wafer, and one end of the axial connecting circuits; then forming a plurality of first grooves horizontally on the first dielectric layer and each of the first grooves is for allowing the one end of the axial connecting circuit to be exposed; next filling a metal paste into the first grooves and a level of the metal paste is higher than a surface of the first dielectric layer; later grinding the metal paste with the level higher than the surface of the first dielectric layer to make a surface of the metal paste flush with the surface of the first dielectric layer and form the first conductive circuit; the second RDL in the step S3, s produced by filling a metal paste into grooves and then grinding the metal paste to form a plurality of the second conductive circuits on over the chip; first paving a second dielectric layer over the second surface of each of the chips, the second surface of the wafer, and one end of the axial connecting circuits; then forming a plurality of second grooves horizontally on the second dielectric layer and each of the second grooves is for allowing the one end of the axial connecting circuit to be exposed; next filling a metal paste into the second grooves and a level of the metal paste is higher than a surface of the second dielectric layer; later grinding the metal paste with the level higher than the surface of the second dielectric layer to make a surface of the metal paste flush with the surface of the second dielectric layer and form the second conductive circuits.

7. The method of manufacturing a chip packaging unit with dual RDLs as claimed in claim 6, wherein the metal pastes of the first conductive circuits in the step S2 and the second conductive circuits in the step S3 include silver paste, nano-scale silver paste, copper paste, and nano-scale copper paste.

8. The method of manufacturing a chip packaging unit with dual RDLs as claimed in claim 5, wherein the external connection bodies in the step S3 are solder balls.
